(19) United States
(12) Patent Application Publication
(10) Pub. No.: US 2005/0039879 A1
(43) Pub. Date: Feb. 24, 2005

(54) Heat transmission member and an electronics device using the member

(75) Inventor: Nobuaki Hanai, Tokyo (JP)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: AGILENT TECHNOLOGIES, INC.

(21) Appl. No.: 10/885,214

(22) Filed: Jul. 6, 2004

(30) Foreign Application Priority Data
Aug. 5, 2003 (JP) 2003-287063

(51) Int. Cl. H05K 7/20

(52) U.S. Cl. 165/46; 165/185

(57) ABSTRACT

Heat-conducting sheets that can adhere closely to heat-generating elements mounted on a substrate are affixed to a pliable graphite sheet and the edge of this graphite sheet is pressed directly to an aluminum heat sink. Non-conductors are used for the heat-conducting sheets.

### FIELD OF THE INVENTION

The present invention pertains to the cooling of heat-generating elements in electronic devices and, in particular, to the cooling of multiple heat-generating elements of different shapes.

### DISCUSSION OF THE BACKGROUND ART

A flexible heat-conducting sheet or graphite sheet has been used in the past in order to cool electronic components mounted on a substrate (for instance, refer to JP (Kokai) 2003-68952 (page 3, FIG. 1) or JP (Kokai) 2003-8263 (page 4, FIG. 2)).

An example of the use of a flexible heat-conducting sheet is shown in FIG. 1. FIG. 1 is a side view. In FIG. 1, a substrate 100 is thermally joined to a metal heat sink 110 by a flexible heat-conducting sheet 120. Multiple heat-generating elements 130a, 130b, 130c, 130d, and 130e of different shapes are mounted on substrate 100. Substrate 100 and heat sink 110 as a rule are rigid bodies. There are limits to the working precision of rigid bodies and therefore, a space is left in between substrate 100 and heat sink 110. Heat-conducting sheet 120 is placed in the spaces between substrate 100 and heat-generating element 130a, etc. and heat sink 110.

Next, an example of the use of a graphite sheet is shown in FIG. 2. FIG. 2 is a side view. In FIG. 2, heat-generating elements 230a, 230b, 230c, and 230d are mounted on a substrate 200. Moreover, heat-generating elements 230a, 230c, and 230d are thermally joined by a graphite sheet 220. Furthermore, heat-generating element 230d is also joined to a heat sink 210 by graphite sheet 220.

There are the following problems with cooling of heat-generating elements using a flexible heat-conducting sheet. First, when heat-generating elements of different shapes are mounted on a substrate, the heights of the heat-generating elements are different. For example, in FIG. 1, the height of heat-generating element 130a is no more than half the height of heat-generating element 130b. Substrate 100 is usually flat and therefore, heat-conducting sheet 120 must be thick so that heat-conducting sheet 120 will contact all of heat-generating elements 130a through 130e. In general, the heat conductivity of heat-conducting sheet 120 is small when compared to that of metal heat-sink 110 and so forth. There will be a reduction in the overall cooling effect with an increase in the thickness of heat-conducting sheet 120. Heat sink 110 should be worked to match the sample of substrate 100 and heat-generating elements 130a through 130e in order to prevent a reduction in the cooling effect. In this case, heat-sink 110 must be worked each time the position of heat-generating elements 130a through 130e changes. This working is uneconomical and reduces development efficiency. Moreover, it is difficult to position the heat sink when heat-generating elements are mounted on both sides of a multi-step substrate.

There are the following problems with the cooling of heat-generating elements using a graphite sheet. First, the graphite sheet is rigid in comparison to the flexible heat-conducting sheet and tends not to bend. Consequently, the graphite sheet cannot adhere to the shorter heat-generating elements (for instance, heat-generating element 230b) when there is an extreme difference in the heights of the heat-generating elements. Moreover, the graphite sheet is a good electrical conductor and therefore, it may short the electronic components on the substrate. A graphite sheet whose surface is coated with insulation and other such graphite sheets have been proposed in recent years, but there is still the possibility of shorting when the graphite sheet is damaged.

The present invention efficiently cools heat-generating elements when many heat-generating elements of different shapes are mounted at high density. The present invention also efficiently cools multiple heat-generating elements mounted on both sides of a multi-step substrate.

### SUMMARY OF THE INVENTION

The present invention is a heat transmission member attached to multiple heat-generating elements of inconsistent shape for transmitting the heat generated by these multiple heat-generating elements to a heat radiation member, wherein it comprises a first heat-conducting sheet and a second heat-conducting sheet that are thermally joined, with this first heat-conducting sheet being an insulator that is flexible enough that it can adhere to these multiple heat-generating elements and the second heat-conducting sheet being so pliable that it can fit this first heat-conducting sheet that adheres to these multiple heat-generating member and having high heat conductivity when compared to this first heat-conducting sheet.

Moreover, the second heat-conducting sheet has a high heat conductivity in the direction of the surface thereof when compared to the heat conductivity in the direction of the thickness thereof, and a relatively high heat conductivity in the direction of thickness thereof in comparison to the heat conductivity of this second heat-conducting sheet.

The second heat-conducting sheet has a part for direct contact with this heat radiation member.

An electronic device comprising a heat transmission member attached to multiple heat-generating elements of inconsistent shape for transmitting the heat generated by these multiple heat-generating elements to a heat radiation member, characterized in that it comprises a first heat-conducting sheet and a second heat-conducting sheet that are thermally joined, with this first heat-conducting sheet being an insulator that is flexible enough that it can adhere to these multiple heat-generating elements and the second heat-conducting sheet being so pliable that it can fit this first heat-conducting sheet that adheres to these multiple heat-generating elements and having a high heat conductivity when compared to this first heat-conducting sheet.

### BRIEF DESCRIPTION OF THE DRAWINGS

FIG. 1 is a drawing showing the heat-conducting sheet of the prior art.

FIG. 2 is a drawing showing the graphite sheet of the prior art.

FIG. 3 is an oblique view showing the first embodiment of the present invention.

FIG. 4 is a side view showing the first embodiment of the present invention.

FIG. 5 is an oblique view showing the second embodiment of the present invention.

FIG. 6 is a side view showing the second embodiment of the present invention.

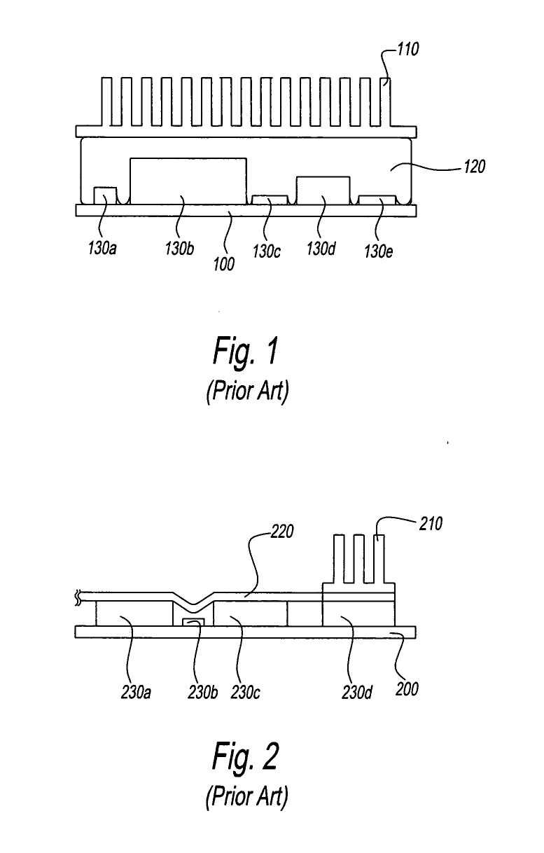

### DETAILED DESCRIPTION OF THE PREFERRED EMBODIMENT

By means of the present invention, heat-generating elements of different shapes can be efficiently cooled when many of these heat-generating elements are mounted at high density. Moreover, by means of the present invention, a multi-step substrate and multiple heat-generating elements mounted on this substrate can be efficiently cooled. Furthermore, by means of the present invention, the shorting of heat-generating elements and other electronic components, and substrates on which these are mounted, can be prevented. By means of the present invention, the cost and the reduction in development efficiency that accompany a change in the position of the heat-generating elements can be prevented.

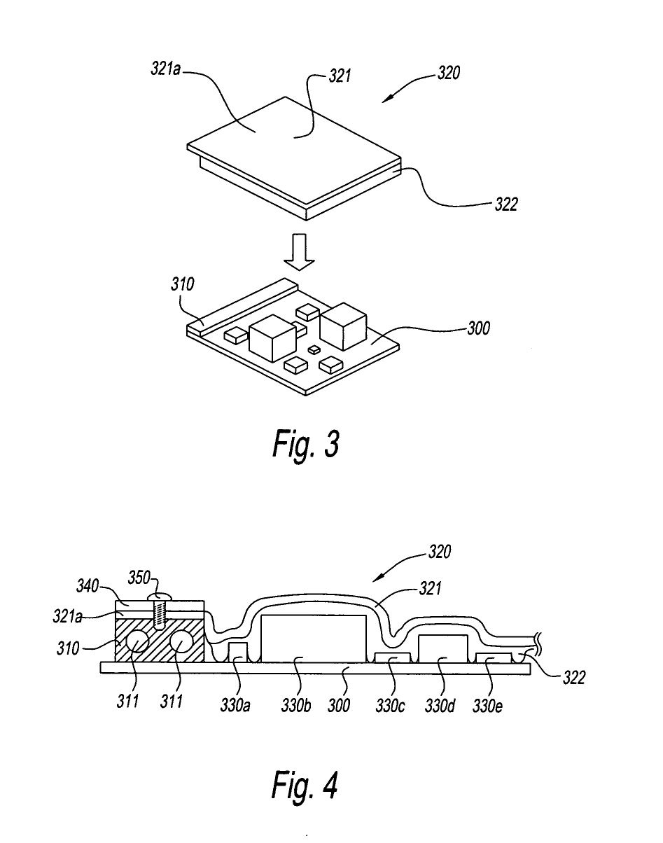

The present invention will now be described in detail based on the embodiments shown in the attached drawings. The first embodiment of the present invention is a printed-circuit board of an electronic measurement apparatus, which is an example of an electronic device. An oblique view thereof is shown in FIG. 3. The electronic measurement apparatus is not limited to a so-called “one-box” measurement apparatus and also includes whole test systems and partial measurement apparatuses comprising test systems. In FIG. 3, a printed-circuit board 300 has an aluminum heat sink 310. Moreover, a heat transmission member 320 is attached, adhering close to the surface of the components of printed-circuit board 300. Heat transmission member 320 is comprised of a graphite sheet 321 and a heat-conducting sheet 322 affixed to the surfaces of one another. Graphite sheet 321 is thermally joined to heat-conducting sheet 322 as a result of this affixing of the heat transmission member. It should be noted that only graphite sheet 321 is exposed at an edge 321a of heat transmission member 320. Graphite sheet 321 is a pliable heat-conducting sheet, and the heat conductivity in the direction of the surface thereof is high in comparison to the heat conductivity in the direction of the thickness thereof. Moreover, graphite sheet 321 has a relatively high heat conductivity in the direction of the thickness thereof when compared to that of heat-conducting sheet 322. Heat sink 310 and heat transmission member 320 work together as a heat radiator. The reference values for heat conductivity are as follows. The heat conductivity of (pure) aluminum is approximately 240 W/mK in both the direction of the surface and the direction of thickness. The heat conductivity of the graphite sheet is approximately 5 W/mK to approximately 20 W/mK in the direction of thickness and approximately 200 W/mK to approximately 800 W/mK in the direction of the surface. The heat conductivity of the heat-conducting sheet is approximately 0.5 W/mK to approximately 10 W/mK in both the direction of the surface and the direction of thickness.

A side view of printed-circuit board 300 is shown in FIG. 4. In FIG. 4, multiple heat-generating elements 330a, 330b, 330c, 330d, and 330e are closely mounted on printed-circuit board 300. Heat-generating elements 330a, 330b, 330c, 330d, and 330e are of inconsistent shapes. Edge 321a of graphite sheet 321 is pressed to heat sink 310 by a plate 340 and a screw 350. Graphite sheet 321 is thermally joined to heat sink 310 as a result of this pressing. Heat-conducting sheet 322 is a non-conductor that is so flexible that it is attached closely adhering to heat-generating elements 330a, 330b, 330c, 330d, and 330e. Graphite sheet 321 is so flexible that it can fit heat-conducting sheet 322 adhering to heat-generating elements 330a, etc. The cross section of heat sink 310 is shown in FIG. 4. A flow path 311 is found on the inside of heat sink 310. The coolant for the cooling of heat sink 310 flows through flow path 311.

By means of the first embodiment of the present invention, heat-conducting sheet 322 is affixed to pliable graphite sheet 321 and therefore, it can adhere closely to heat-generating elements 330a, etc. of different shapes, even if it is thin. Thin heat-conducting sheet 322 can efficiently transmit heat from multiple heat-generating elements 330a, etc. with different shapes mounted at high density to graphite sheet 321. Moreover, graphite sheet 321 can quickly transmit the heat that has been transmitted from heat-conducting sheet 322 to heat sink 310. Consequently, heat transmission member 320 can efficiently cool these heat-generating elements when many heat-generating elements of different shapes are mounted at high density. Furthermore, heat-conducting sheet 322 is a non-conductor and therefore, shorting accidents of printed-circuit board 300, or of heat-generating elements 330, etc. or other electronic components mounted on printed-circuit board 300 can be prevented. In addition, heat-conducting sheet 322 has sufficient flexibility and is supported by a graphite sheet 321 that is pliable and therefore, it can be used as is, even if the placement of heat-generating elements 330a, etc. changes. As a result, economics and development efficiency are improved when compared to the prior art.

Furthermore, it is possible to reduce the size of the electronic device by the present invention. For instance, many substrates on which many heat-generating elements of different shapes have been mounted at high density are placed at high density inside the test head of a semiconductor tester, which is one example of an electronic measurement apparatus. By means of the present invention, the space between these substrates can be as close as possible and therefore, the size of the test head can be reduced.

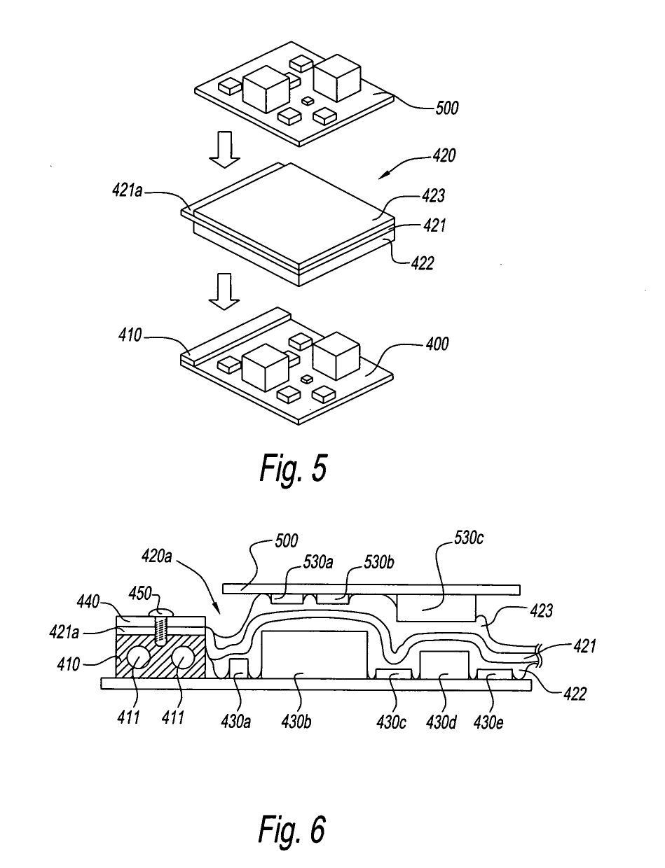

Next, a second embodiment of the present invention will be described. The second embodiment of the present invention is a double-sided printed-circuit board with a multi-step structure of an electronic measurement apparatus, which is one example of an electronic device. An oblique view thereof is shown in FIG. 5. The electronic measurement apparatus is not limited to a so-called “one-box” measurement apparatus and also includes whole test systems and partial measurement apparatuses comprising test systems. In FIG. 5, electronic components including heat-generating elements are mounted on both sides of a printed-circuit board 400 and a printed-circuit board 500. Printed-circuit board 400 comprises an aluminum heat sink 410. A heat transmission member 420 is comprised of heat-conducting sheets 422 and 423 affixed to both sides of a graphite sheet 421. Graphite sheet 421 is thermally joined to heat-conducting sheet 422 and heat-conducting sheet 423 as a result of affixing these sheets. Heat-transmission member 420 is attached by closely adhering to the surface of the components on printed-circuit board 400 and to the surface of the components on printed-circuit board 500. Only graphite sheet 421 is exposed at an edge 421a of heat transmission member 420. Graphite sheet 421 has a higher heat conductivity in the direction of the surface thereof than the heat conductivity in the direction of the thickness thereof. Moreover, graphite sheet 421 is a flexible heat-conducting sheet and the heat conductivity in the direction of the thickness thereof is relatively high in comparison to the heat conductivity in the direction of the thickness or the direction of the surface of heat-conducting sheet 422 and heat-conducting sheet 423. Heat sink 410 and heat transmission member 420 together act as a radiator. The reference values for heat conductivity are the same as indicated in the first embodiment.

The side view of printed-circuit board 400 and printed-circuit board 500 here is shown in FIG. 6. In FIG. 6, multiple heat-generating elements 430a, 430b, 430c, 430d, and 430e are closely mounted on printed-circuit board 400. Moreover, multiple heat-generating elements 530a, 530b, 530c, 530d, and 530e are closely mounted on printed-circuit board 500. Heat-generating elements 430a, 430b, 430c, 430d, 430e, 530a, 530b, 530c, 530d, and 530e are of inconsistent shapes. Edge 421a of graphite sheet 421 is pressed to heat sink 410 by a plate 440 and a screw 450. Graphite sheet 421 is thermally joined to heat sink 410 as a result of this pressing. Heat-conducting sheet 422 is a non-conductor that is so flexible that it is attached closely adhering to heat-generating elements 430a, 430b, 430c, 430d, and 430e. Heat-conducting sheet 422 is a non-conductor that is so flexible that it is attached closely adhering to heat-generating elements 530a, 530b, 530c, 530d, and 530e. Graphite sheet 421 is so flexible that it can fit heat-conducting sheet 422 adhering to heat-generating elements 430a, etc. The cross section of heat sink 410 is shown in FIG. 6. A flow path 411 is found on the inside of heat sink 410. A coolant for cooling heat sink 410 flows through flow path 411.

By means of this second embodiment, heat-conducting sheets 422 and 423 are placed on either side of graphite sheet 421 and therefore, the heat from heat-generating elements 430a, etc. that are within a narrow space can be efficiently transmitted to heat sink 410. As a result, the heat-generating elements that are mounted close to one another on both sides of the printed-circuit board can be efficiently cooled. It is not necessary to place a heat sink between printed-circuit board 400 and printed-circuit board 500.

When diamond powder is placed unexposed inside the heat conducting sheets in the above-mentioned two embodiments, the heat conductivity of the heat-conducting sheets is improved. Good cooling effects can thereby be expected, even if the heat-conducting sheets are thick.

Moreover, another heat transmission member can be used for the graphite sheets of the above-mentioned two embodiments as long as it is a member in sheet form that is pliable and has a higher heat conductivity than the heat-conducting sheets. For instance, a pliable diamond sheet can be used in place of the graphite sheet.

Furthermore, the heat-conducting sheets of the above-mentioned two embodiments should adhere closely to multiple heat-generating elements of different shapes. For instance, silicon rubber sheets or non-silicone acrylic rubber sheets can be used as the heat-conducting sheet. In addition, it is not necessary to use the same type or shape (including thickness) of heat-conducting sheet when heat-conducting sheets are affixed to either side of the graphite sheet. The sheets can be individually selected in accordance with the shape and amount of heat generated by the component to which they will closely adhere, and so forth.

Moreover, heat sinks with a smaller heat capacity or specific heat are preferred in the above-mentioned two embodiments. Therefore, the heat sink can be made not only of aluminum, but also of copper and other such materials. The heat sink should be placed as close as possible to the heat-generating elements. The heat sink is connected to the edge of the heat transmission member (edge of the graphite sheet) in the above-mentioned two embodiments, but the placement of the heat sink is not limited to this position.

The present invention is effective when mounting many heat-generating elements of different shapes at high density. Therefore, it is also effective for heat-generating elements in other electronic devices.

1. A heat transmission member attached to multiple heat-generating elements of inconsistent shape for transmitting the heat generated by said multiple heat-generating elements to a heat radiation member, wherein said heat transmission member comprises:
a first heat-conducting sheet, wherein said first heat-conducting sheet is an insulator that is flexible enough that it can adhere to said multiple heat-generating elements; and
a second heat-conducting sheet that is thermally joined to said first heat-conducting sheet, wherein said second heat-conducting sheet is so pliable that it can fit said first heat-conducting sheet that adheres to said multiple heat-generating member and having a high heat conductivity when compared to said first heat-conducting sheet.

2. The heat transmission member according to claim 1, wherein said second heat-conducting sheet has a high heat conductivity in the direction of the surface thereof when compared to the heat conductivity in the direction of the thickness thereof, and a relatively high heat conductivity in the direction of the thickness thereof in comparison to the heat conductivity of said first heat-conducting sheet.

3. The heat transmission member according to claim 1, wherein said second heat-conducting sheet has a part for direct contact with said heat radiation member.

4. The heat transmission member according to claim 1, wherein said second heat-conducting sheet is a graphite sheet or a diamond sheet.

5. The heat transmission member according to claim 1, further comprising a diamond powder on the inside of said first heat-conducting sheet.

6. An electronic device comprising a heat transmission member attached to multiple heat-generating elements of inconsistent shape for transmitting the heat generated by said multiple heat-generating elements to a heat radiation member, wherein said heat transmission member comprises:
a first heat-conducting sheet, wherein said first heat-conducting sheet is an insulator that is flexible enough that it can adhere to said multiple heat-generating elements; and
a second heat-conducting sheet that is thermally joined to said first heat-conducting sheet, wherein said second heat-conducting sheet is so pliable that it can fit said first heat-conducting sheet that adheres to said multiple heat-generating member and having a high heat conductivity when compared to said first heat-conducting sheet.

7. The electronic device according to claim 6, wherein said second heat-conducting sheet has a high heat conductivity in the direction of the surface thereof when compared to the heat conductivity in the direction of the thickness thereof, and a relatively high heat conductivity in the direction of the thickness thereof in comparison to the heat conductivity of said first heat-conducting sheet.

8. The electronic device according to claim 6, wherein said second heat-conducting sheet has a part for direct contact with said heat radiation member.

9. The electronic device according to claim 6, wherein said second heat-conducting sheet is a graphite sheet or a diamond sheet.

10. The electronic device according to claim 6, further comprising a diamond dust inside said first heat transmitting sheet.
